(19) United States
(12) Patent Application Publication
(10) Pub. No.: US 2026/0051359 A1
(43) Pub. Date: Feb. 19, 2026

(54) APPARATUSES, SYSTEMS AND METHODS FOR BANK OPTION BROADCASTS

(71) Applicant: Micron Technology, Inc., Boise, ID (US)

(72) Inventor: Jacob Rice, Boise, ID (US)

(73) Assignee: Micron Technology, Inc., Boise, ID (US)

(21) Appl. No.: 19/287,007

(22) Filed: Jul. 31, 2025

Related U.S. Application Data
(60) Provisional application No. 63/683,841, filed on Aug. 16, 2024.

(51) Int. Cl. G11C 29/44; G11C 29/14; G11C 29/30

(52) U.S. Cl. CPC G11C 29/44; G11C 29/14; G11C 29/30

(57) ABSTRACT

The present disclosure is generally directed to broadcasting bank option information to one or more memory banks in a memory device. In some instances, bank option information can be associated with a trimming operation for a memory bank. Each memory bank in a memory array can receive bank option information on a per bank basis. The bank option information may be broadcast before, during, or after the broadcast of a line repair information (e.g., column repair information). The bank option information enables the operation of each memory bank to be uniquely improved or optimized.

### CROSS-REFERENCE TO RELATED APPLICATIONS

This application claims the filing benefit of U.S. Provisional Application No. 63/683,841, filed Aug. 16, 2024. This application is incorporated by reference herein in its entirety and for all purposes.

### BACKGROUND

Memory devices, such as dynamic random-access memory (DRAM), include an array of memory cells that may be organized into rows (word lines) and columns (bit lines). Information may be stored in the memory cells, typically as single bit of information as either a logical high (e.g., a “1”) or a logical low (e.g., a “0”). At various points in the manufacturing and the use of a memory device, one or more memory cells may fail (e.g., become unable to store information, be inaccessible by the memory device, etc.) and may need to be repaired. The memory device may perform repair operations on a row-by-row basis and/or column-by-column basis.

These repair operations are typically implemented as broadcast operations. A memory device can also broadcast global option information that is used to improve or optimize the operation and/or the performance of the memory device. In some instances, a memory array includes multiple memory banks, and the global option information applies globally to all of the memory banks.

### BRIEF DESCRIPTION OF THE DRAWINGS

Non-limiting and non-exhaustive examples are described with reference to the following Figures. The elements of the drawings are not necessarily to scale relative to each other. Identical reference numerals have been used, where possible, to designate identical features that are common to the figures.

FIG. 1 illustrates a block diagram of an example semiconductor device according to an embodiment of the disclosure;

FIG. 2 illustrates a block diagram representing an example memory device according to an embodiment of the disclosure;

FIG. 3 illustrates a flowchart of an example method of operating a memory device according to an embodiment of the disclosure;

FIG. 4 illustrates a flowchart of an example method of broadcasting column repair information and bank option information according to an embodiment of the disclosure;

FIG. 5 illustrates an example truth table for a portion of the column repair information according to an embodiment of the disclosure;

FIG. 6 illustrates an example timing diagram of signals involved in broadcast operations according to an embodiment of the disclosure;

FIG. 7 illustrates a block diagram of an example fuse array and fuse logic circuit according to an embodiment of the disclosure;

FIG. 8 illustrates example signal lines in a fuse bank address bus according to an embodiment of the disclosure;

FIG. 9 illustrates a block diagram of a first example of a bank option detection circuit according to an embodiment of the disclosure;

FIG. 10 illustrates a block diagram of an example arrangement of the bank option detection circuits shown in FIG. 9 according to an embodiment of the disclosure;

FIG. 11 illustrates a block diagram of an example fuse data select circuit according to an embodiment of the disclosure;

FIG. 12 illustrates an example block diagram of a fuse broadcast flag logic circuit according to an embodiment of the disclosure; and

FIG. 13 illustrates a block diagram of a second example of a bank option detector circuit according to an embodiment of the disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part hereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

The present disclosure is generally directed to broadcasting bank option information to one or more memory banks in a memory device. Bank option information can be associated with trimming, timing adjustments, and functionality changes on a per memory bank basis. Generally, a trimming operation improves or optimizes an operational parameter or parameters of a memory bank to improve the operation and/or the performance of that memory bank. One non-limiting nonexclusive example of an operational parameter of a memory bank that can be trimmed is sense amplifier settings. An example of a functionality change is a fuse state that can change a column repair scheme on a per bank basis.

Each memory bank in a memory array can receive column repair information and bank option information on a per bank basis. The bank option information is broadcast during (e.g., immediately before, within, or immediately after) the broadcast of the line repair information (e.g., column repair information). The bank option information enables the operation of each memory bank to be uniquely improved or optimized.

A memory device typically performs various broadcast operations when a semiconductor memory device is initialized, and the broadcast operations can be performed in a particular order. In one embodiment, global option information is broadcast first, where the global option information is used to improve or optimize certain operations of the memory device. The global option information can be applied to the memory banks (e.g., the same trim operation applies to all of the memory banks) and/or to periphery circuits in the memory device. After the global option information is broadcast, row repair information may be broadcast, followed by the broadcast of column repair information. In the example embodiments disclosed herein, bank option information associated with a particular memory bank is broadcast after the column repair information has been broadcast to that particular memory bank, although other embodiments are not limited to this implementation. The bank option information applies to the particular memory bank that received the bank option information and not to the other memory banks. The process of broadcasting column repair information and bank option information repeats for each memory bank until all of the memory banks have received column repair information and bank option information. In this manner, a memory bank can be individually improved or optimized using the bank option information associated with that memory bank.

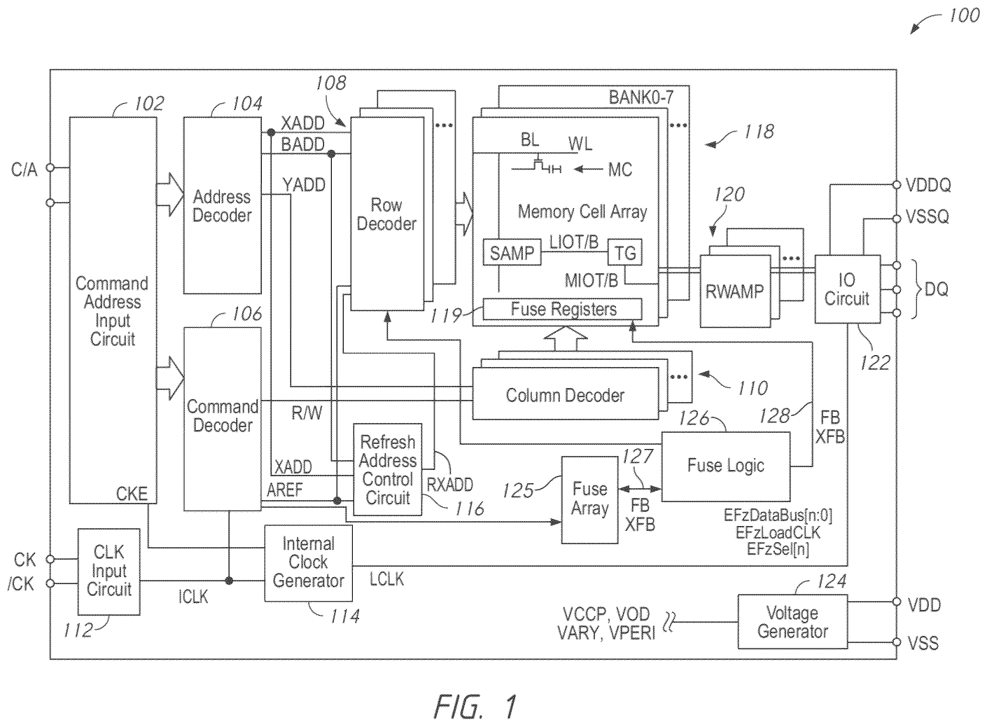

FIG. 1 illustrates a block diagram of an example semiconductor device 100 according to an embodiment of the disclosure. The semiconductor device 100 may include, without limitation, a dynamic random-access memory (DRAM), a double data rate (DDR) memory, a low power double data rate (LPDDR) memory, or other type of memory. The semiconductor device 100 includes a memory array 118. The memory array 118 is shown as including a plurality of memory banks. In the embodiment of FIG. 1, the memory array 118 is shown as including eight memory banks BANK0-BANK7. More or fewer memory banks may be included in the memory array 118 of other embodiments.

Each memory bank includes a plurality of word lines WL (e.g., rows), a plurality of bit lines BL and /BL (e.g., columns or digit lines), and a plurality of memory cells MC arranged at intersections of the plurality of word lines WL and the plurality of bit lines BL and /BL. The selection of the word line WL is performed by a row decoder 108 and the selection of the bit lines BL and /BL is performed by a column decoder 110. In the embodiment of FIG. 1, the row decoder 108 includes a respective row decoder for each memory bank and the column decoder 110 includes a respective column decoder for each memory bank.

The bit lines BL and B/L are coupled to a respective sense amplifier (SAMP). Read data from the bit line BL or /BL is amplified by the sense amplifier SAMP and transferred to read/write amplifiers 120 over complementary local data lines (LIOT/B), transfer gate (TG), and complementary main data lines (MIOT/B). Conversely, write data outputted from the read/write amplifiers 120 is transferred to the sense amplifier SAMP over the complementary main data lines MIOT/B, the transfer gate TG, and the complementary local data lines LIOT/B, and written in the memory cell MC coupled to the bit line BL or /BL.

The semiconductor device 100 also includes a fuse array 125, which contains a plurality of non-volatile storage elements which may store information about addresses in the memory array 118 (e.g., row repair information, column repair information), global option information, and bank option information. The fuse array 125 includes non-volatile storage elements, such as fuses or anti-fuses. Each fuse may be in a first state where it is conductive and may be ‘blown’ to make the fuse insulating instead. Each anti-fuse may be in a first state which is non-conductive, until it is blown to make the anti-fuse conductive instead. Each fuse/anti-fuse may permanently change when it is blown. Each fuse/anti-fuse may be considered to be a bit, which is in one state before it is blown, and permanently in a second state after it's blown. For example, a fuse may represent a logical low before it is blown and a logical high after it is blown, while an anti-fuse may represent a logical high before it is blown and a logical low after it is blown. It should be understood that discussions of fuses as used herein may generally refer to either fuses or anti-fuses and that embodiments may use fuses, anti-fuses, or a combination thereof in the fuse array 125.

Specific groups of fuses/anti-fuses may be represented by a fuse bus address (FBA), which may specify the physical location of each of the fuses/anti-fuses in the group within the fuse array 125. The group of fuses/anti-fuses associated with a particular FBA may in turn be used to encode an address associated with one or more memory cells of the memory array 118. For example, the state of a group of fuses/anti-fuses may represent a memory line address (e.g., either a row address XADD or a column address YADD). FBAs can be provided to the fuse array 125 on a fuse bus (FB and xFB) 127 and in response, the address information in the fuse array 125 may be ‘scanned’ out along a fuse bus (FB and xFB) 128 to fuse registers 119. Each fuse register may be associated with a particular memory line of the memory array 118. In some embodiments, the redundant memory lines of the memory array 118 (e.g., the rows/columns designated for use in repair operations) may be associated with one of the fuse registers 119. The address stored in a given group of fuses/anti-fuses (e.g., a group specified by an FBA) may be scanned out from the fuse array 125 along the fuse buses 127, 128 and latched by a particular fuse register 119. The fuse logic circuit 126 may determine which address broadcast along the fuse bus 128 is latched in which fuse register 119. In this manner, an address stored in the fuse array 125 may be associated with a particular memory line of the memory array 118. When an incoming row/column address XADD or YADD matches the address stored in the fuse register 119, it may then direct access commands to the memory line associated with that fuse register 119.

The fuse registers 119 may each contain a number of fuse latches, each of which stores a bit of the stored memory line or memory bank address. Since row addresses XADD and column addresses YADD may be different lengths, fuse registers 119 associated with redundant rows may have a different number of fuse latches than fuse registers 119 associated with redundant columns. Each of the fuse registers may be coupled to a fuse match circuit, which compares the incoming memory line address as part of an access operation to the address stored in the fuse register 119 to determine if there is a match. If there is a match, the redundant memory line associated with the fuse register 119 may be activated.

Some components of the match circuits, as well as other control logic of the fuse registers 119 may be shared between multiple fuse registers 119. For example, in some embodiments, match circuits may be shared by a number of different fuse registers 119. In some embodiments, a dynamic logic circuit may manage which of the fuse registers 119 coupled to a match circuit is active to provide the address stored in that fuse registers 119 for a comparison operation to determine if an accessed memory line address matches the stored address. In some embodiments, the dynamic logic circuit may also manage timing of the comparison operation.

The group of fuses/anti-fuses associated with a particular FBA may also be used to store global option information or bank option information. FBAs can be provided to the fuse array 125 on the fuse bus (FB and xFB) 127 and in response, the global option information or the bank option information in the fuse array 125 may be ‘scanned’ out along the fuse bus (FB and xFB) 127 to the fuse logic circuit 126. The fuse logic circuit 126 can provide the global option information and the bank option information to latches for storage and use by the semiconductor device 100 and the memory banks of the memory array 118, respectively.

The semiconductor device 100 may employ a plurality of external terminals that include command and address (C/A) terminals coupled to a command and address bus to receive commands and addresses, and a CS signal, clock terminals to receive clocks CK and /CK, data terminals DQ to provide data, and power supply terminals to receive power supply potentials VDD, VSS, VDDQ, and VSSQ.

The clock terminals are supplied with external clocks CK and /CK that are provided to an input circuit 112. The external clocks may be complementary (e.g., 180 degrees out of phase). The input circuit 112 generates an internal clock ICLK based on the CK and /CK clocks. The ICLK clock is provided to the command decoder 106 and to an internal clock generator 114. The internal clock generator 114 provides various internal clocks LCLK based on the ICLK clock. The LCLK clocks may be used for timing operations of various internal circuits. The internal data clocks LCLK are provided to the input/output circuit 122 to time operation of circuits included in the input/output circuit 122, for example, to data receivers to time the receipt of write data.

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a row activate command ACT. When the row activate command ACT is received, a bank address BADD and a row address XADD are timely supplied with the row activate command ACT.

The semiconductor device 100 may receive an access command which is a read command. When a read command is received, and a bank address BADD and a column address YADD are timely supplied, read data is read from memory cells in the memory array 118 corresponding to the row address XADD and column address YADD. For example, the row decoder 108 may access the word line associated with the row latch 119 which has an address which matches XADD. The read command is received by the command decoder 106, which provides internal commands so that read data from the memory array 118 is provided to the read/write amplifiers 120. The row decoder 108 may match the address XADD to an address stored in a row latch 119, and then may access the physical row associated with that row latch 119. The read data is output to outside from the data terminals DQ via the input/output circuit 122.

The semiconductor device 100 may receive an access command which is a write command. When the write command is received, and a bank address BADD and a column address YADD are timely supplied, write data supplied to the data terminals DQ is written to a memory cell in the memory array 118 corresponding to the row address XADD and column address YADD. The write command is received by the command decoder 106, which provides internal commands so that the write data is received by data receivers in the input/output circuit 122. The row decoder 108 may match the address XADD to an address stored in a row latch 119, and then access the physical row associated with that row latch 119. Write clocks may also be provided to the external clock terminals for timing the receipt of the write data by the data receivers of the input/output circuit 122. The write data is supplied via the input/output circuit 122 to the read/write amplifiers 120, and by the read/write amplifiers 120 to the memory array 118 to be written into the memory cell MC.

The semiconductor device 100 may also receive commands causing it to carry out an auto-refresh operation. The refresh signal AREF may be a pulse signal which is activated when the command decoder 106 receives a signal which indicates an auto-refresh command. In some embodiments, the auto-refresh command may be externally issued to the semiconductor device 100. In some embodiments, the auto-refresh command may be periodically generated by a component of the semiconductor device 100. In some embodiments, when an external signal indicates a self-refresh entry command, the refresh signal AREF may also be activated. The refresh signal AREF may be activated once immediately after command input, and thereafter may be cyclically activated at desired internal timing. Thus, refresh operations may continue automatically. A self-refresh exit command may cause the automatic activation of the refresh signal AREF to stop and return to an IDLE state.

The refresh signal AREF is supplied to the refresh address control circuit 116. The refresh address control circuit 116 supplies a refresh row address RXADD to the row decoder 108, which may refresh a word line WL indicated by the refresh row address RXADD. The refresh address control circuit 116 may control a timing of the refresh operation and may generate and provide the refresh address RXADD. The refresh address control circuit 116 may be controlled to change details of the refreshing address RXADD (e.g., how the refresh address is calculated, the timing of the refresh addresses), or may operate based on internal logic. In some embodiments, the refresh address control circuit 116 may perform both auto-refresh operations, where the word lines of the memory array 118 are refreshed in a sequence, and targeted refresh operations, where specific word lines of the memory are targeted for a refresh out of sequence from the auto-refresh operations.

The power supply terminals are supplied with power supply potentials VDD and VSS. The power supply potentials VDD and VSS are supplied to an internal voltage generator circuit 124. The internal voltage generator circuit 124 generates various internal potentials VCCP, VOD, VARY, VPERI, and the like based on the power supply potentials VDD and VSS supplied to the power supply terminals. The power supply terminals are also supplied with power supply potentials VDDQ and VSSQ. The power supply potentials VDDQ and VSSQ are supplied to the input/output circuit 122.

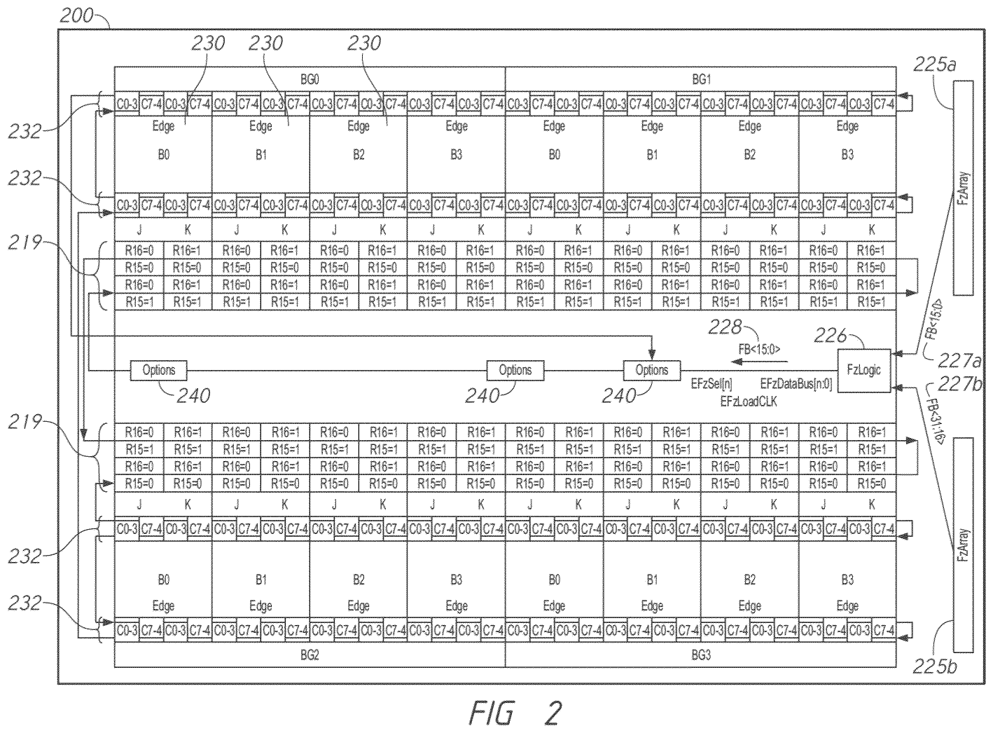

FIG. 2 is a block diagram representing a memory array 200 according to an embodiment of the disclosure. FIG. 2 shows the transmission path of a fuse bus 228 from a pair of fuse arrays 225a and 225b through a memory array 200. In some embodiments, the memory array 200 may be an implementation of the memory array 118 of FIG. 1. However, the memory array 200 includes sixteen (16) memory banks 230 rather than the eight memory banks previously described with reference to the memory array 118. The sixteen memory banks 230 are organized into four bank groups (BG0 - BG3) of four memory banks 230 each. Each of the memory banks 230 is associated with a set of fuse latches such as row latches 219 and column latches 232.

Addresses may be scanned out along a fuse bus 228 from the fuse array 225a, 225b. In the particular embodiment of FIG. 2, there may be a pair of fuse arrays 225a and 225b. Each of the fuse arrays 225a, 225b may store a number of addresses, global option information, and bank option information encoded in the conductive state of fuses and/or anti-fuses, which may be streamed out along the fuse bus 228 to the fuse registers such as the row latches 219 and column latches 232.

In some embodiments, the fuse array 225a may include anti-fuses, and may be a non-inverting fuse array (since the default value of the anti-fuses is a low logical level) and the fuse array 225b may include fuses and be an inverting fuse array. It may be necessary to ‘invert’ an address (e.g., swap low logical levels for high logical levels and vice versa) before providing an address based on the inverting fuse array 225b. It should be understood that other methods of organizing addresses in the fuse array(s) may be used in other embodiments. For example, a single fuse array may be used with only fuses, only anti-fuses, or a mix thereof.

During a broadcast operation, the fuse arrays 225a, 225b may broadcast the row addresses and the column addresses stored in the fuse arrays 225a, 225b along the fuse bus 228. In the particular embodiment of FIG. 2, during the broadcast operation the fuse logic circuit 226 may receive a portion of the addresses along fuse bus portion 227a from the fuse array 225a, and a portion of the addresses along fuse bus portion 227b from the fuse array 225b. The fuse logic circuit 226 may combine the addresses onto the fuse bus 228 by alternating whether the addresses from the first fuse bus portion 227a or the second fuse bus portion 227b are provided along the fuse bus 228. For clarity, the addresses provided along the fuse bus portion 227a may be referred to as ‘even’ addresses and the addresses provided along the fuse bus portion 227b may be referred to as ‘odd’ addresses. It should be understood that even and odd addresses refer to the fuse array 225a, 225b the address is stored in, and that both fuse bus portions 227a-b may include addresses with numerical values which are both even and odd. In some embodiments, the fuse bus portions 227a, 227b and the fuse bus 228 may be implementations of the fuse bus 127 and the fuse bus 128, respectively, of FIG. 1.

During global option and bank option broadcast operations, the fuse arrays 225a, 225b may broadcast the global option information and the bank option information stored in the fuse arrays 225a, 225b along the fuse bus 228. In the particular embodiment of FIG. 2, during the broadcast operations during (e.g., immediately before, within, or immediately after), the fuse logic circuit 226 may receive global option information and bank option information along fuse bus portion 227a from the fuse array 225a, and global option information and the bank option information along fuse bus portion 227b from the fuse array 225b.

The fuse logic circuit 226 may provide information along the fuse bus 228. The fuse logic circuit 226 may alternate between providing the even addresses from fuse bus portion 227a and the odd addresses from fuse bus portion 227b along the fuse bus 228. The fuse logic circuit 226 may also perform one or more operations based on the information of the fuse bus. For example, during a repair operation, the fuse logic circuit 226 may provide a select signal (e.g., such as a row select signal or a column select signal) which indicates which fuse register a given address along the fuse bus 228 is latched in.

The fuse logic circuit 226 may provide information to the fuse bus 228 (e.g., global option information), which may pass the information through one or more options circuits 240. The options circuits 240 may include various settings of the memory which may interact with the addresses along the fuse bus 228. For example, the options circuits 240 may include fuse settings, such as the test mode and power supply fuses. Information stored in the fuse arrays 225a, 225b may be latched and/or read by the options circuits 240, which may then determine one or more properties of the memory based on the options data provided along the fuse bus 228.

After passing through the options circuits 240, the fuse bus 228 may pass through the row latches 219 for all of the memory banks 230 before passing through the column latches 232 for all of the memory banks 230. As well as providing information (including address information) along the fuse bus 228, the fuse logic circuit 226 may also provide one or more select signals along the fuse bus 228. The select signals may be associated with a particular packet of information along the fuse bus and may determine which circuit along the fuse bus 228 the particular packet of information is associated with. For example, if a row latch select signal is in an active state, it may indicate that the packet of information is to be stored in a row latch 219. In some embodiments, this may overwrite an address already stored in the row latch 219 with the address from the fuse bus 228. Further select signals may be used to specify a particular location of the specific row latch 219 which is intended to store the packet of information (e.g., a bank group select signal, a bank select signal, etc.).

Another broadcast operation the fuse logic circuit 226 may participate in is a bank option broadcast operation. As described earlier, bank option information provides per bank trimability that enables each memory bank to be trimmed (e.g., tuned or optimized) differently from the other memory banks. The fuse logic circuit 226 may provide bank option information to the fuse bus 228, which may pass the bank option information through the row latches 219 for all of the memory banks 230 before passing through the column latches 232 for particular memory banks 230.

The fuse logic circuit 226 is configured to detect a start of a bank option broadcast operation. In some embodiments, the fuse logic circuit 226 is configured to perform the bank option broadcast operation at some point during the column address broadcast operation for a memory bank 230 (e.g., at the start, the middle, or the end of the column address broadcast operation). The fuse logic circuit 226 is further configured to detect the end of the bank option broadcast for the memory bank 230 and repeat the column address broadcast and the bank option broadcast for each of the memory banks 230.

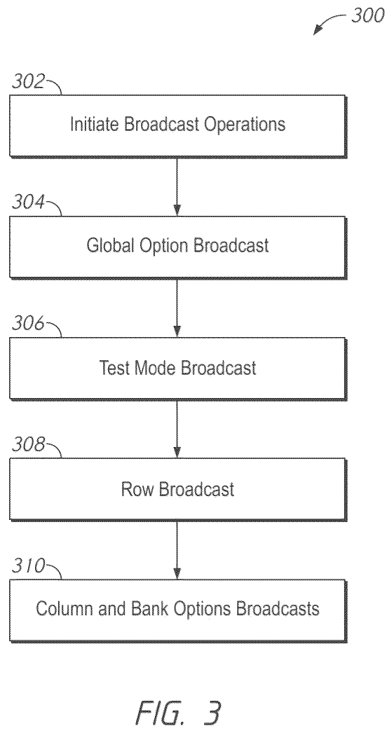

FIG. 3 illustrates a flowchart of an example method 300 of operating a memory device according to an embodiment of the disclosure. The method 300 begins with the initiation of broadcast operations at block 302. The broadcast operations broadcast information that is stored in a fuse array (e.g., the fuse array 125 in FIG. 1). In a non-limiting nonexclusive example, the broadcast operations may be performed during initialization of the memory device.

At block 304, a global options broadcast is performed. The global options broadcast can transmit global option information for the memory device. The global option information can act on all of the memory banks and/or periphery circuitry in the memory device. The global option information may include information for various operations of the memory device. For example, the global option information can be used to configure one or more operational parameters of the memory device. Example operational parameters include, but are not limited to, power supply settings and sense amplifier settings.

At block 306, a test mode broadcast is performed. In one embodiment, the test mode broadcast uses the global option information to enable various functionalities of local circuits distributed throughout the memory device. Example functionalities include, but are not limited to, trims, offsets, and function changes to the local circuits.

At block 308, one or more row broadcasts are performed. The row broadcasts can provide row repair information for a memory device. The row repair information can include row addresses that are provided as part of the repair operations. As described earlier, during a row repair operation, a row address associated with a defective row may be redirected so that it is associated with a redundant row instead. In one embodiment, the row repair information is broadcast on a per memory bank basis. The row repair information for one particular memory bank is broadcast (i.e., starts and ends), the row repair information for another memory bank is broadcast, and so on. The process repeats until the row repair information for all of the memory banks has been broadcast.

At block 310, one or more column broadcasts and bank option broadcasts are performed. The column broadcasts can provide column repair information for the memory device. The bank option broadcasts may provide bank option information for the memory banks of the memory device. The column repair information can include column addresses that are provided as part of a repair operation, and the bank option information may include information to improve or optimize one or more operational parameters of a memory bank. In one embodiment, the column repair information and the bank option information are broadcast on a per memory bank basis.

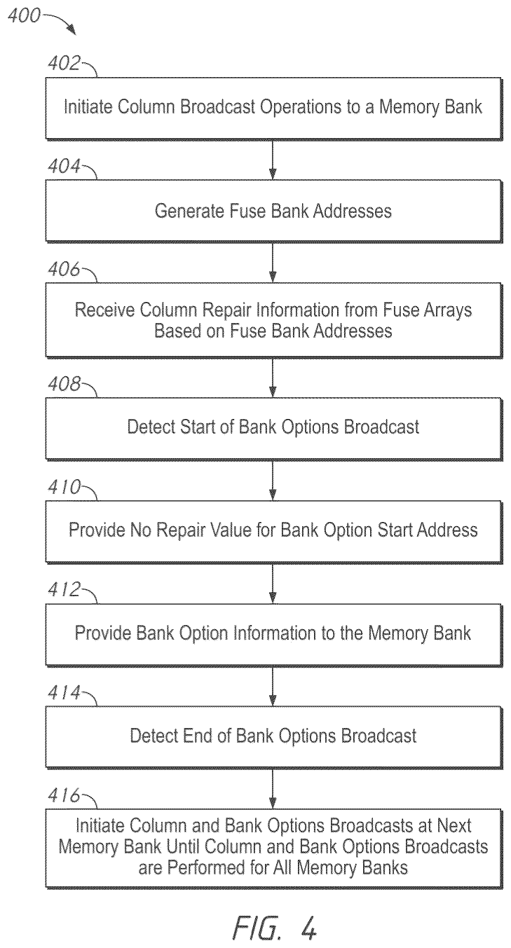

FIG. 4 illustrates a flowchart of an example method 400 of broadcasting column repair information and bank option information according to an embodiment of the disclosure. The illustrated method 400 is performed on a per memory bank basis, although other embodiments are not limited to this implementation. At block 402, a column broadcast operation to a memory bank is initiated. At block 404, FBAs are generated and output to the fuse array. In response to the FBAs, the fuse array broadcasts the column repair information stored in the fuse array onto a fuse bus at block 406 (e.g., the fuse bus 128 in FIG. 1 or the fuse buses 227a, 227b in FIG. 2). In one embodiment, the FBAs are generated by the fuse logic circuit and the column repair information read out of the fuse array is received by the fuse logic circuit (e.g., the fuse logic circuit 126 in FIG. 1 or the fuse logic circuit 226 in FIG. 2).

A start of a bank option broadcast operation is detected at block 408. In one embodiment, the start of the bank option broadcast operation is detected based on a respective FBA (i.e., a bank option start address). In another embodiment, the start of the bank option broadcast operation is detected based on a signal level of a column flag signal. The bank option broadcast operation can transmit the bank option information to the memory bank that received the column repair information broadcast at block 406. In one embodiment, a fuse logic circuit is configured to detect a start and an end of a bank option broadcast (e.g., the fuse logic circuit 126 of FIG. 1 or 226 of FIG. 2).

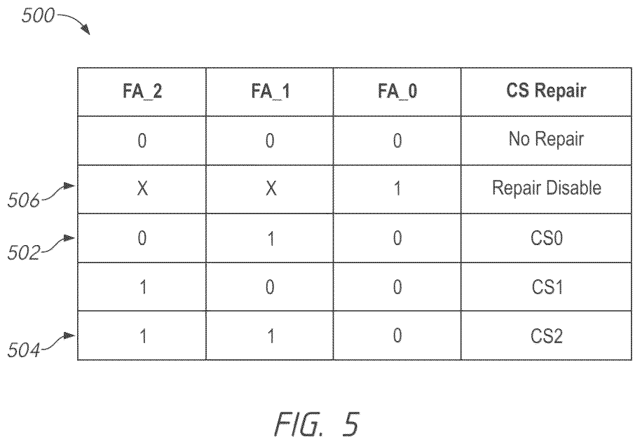

At block 410, a no repair value is provided for the bank option start address. The no repair value is used to indicate the column repair information is not available or is not provided for the bank option start address. The no repair value is discussed in more detail in conjunction with FIG. 5.

At block 412, bank option information is provided to the memory bank. In one embodiment, the bank option information is provided to fuse latches associated with the memory bank. At block 414, the end of the bank option broadcast is detected. The end of a bank option broadcast may be detected in one of several ways. In one embodiment, a respective FBA (also referred to as a bank option end address) may be detected. The bank option end address is the last FBA in the bank option broadcast. In another embodiment, a count can be used to indicate the end of the bank option broadcast. For example, a count can begin at the start of the bank option broadcast. The count may represent a count of a clock signal, such as a fuse load clock (e.g., the rising edges of the fuse load clock). The end of the bank option broadcast may be determined based on the count reaching a specific value, where the specific value represents the end of the bank option broadcast. The specific value of the count may be referred to as an end count value.

At block 416, the column and the bank option broadcasts are initiated at the next memory bank. The column and the bank option broadcasts continue until the column and the bank option broadcasts are performed for all of the memory banks.

FIG. 5 illustrates an example truth table 500 for a portion of the column repair information according to an embodiment of the disclosure. In the illustrated embodiment, the least significant bit FA_0 of the column repair information is used to indicate whether the column broadcast operation is disabled (i.e., a bank option broadcast is in process). In FIG. 5, the FA_2 bit and the FA_1 bit of the column repair information are used to indicate the column to receive the column repair information. For example, when the FA_2 bit is set to zero and the FA_1 bit is set to one (row 502), the column repair is on CS0. When the FA_2 bit is set to one and the FA_1 bit is set to one (row 504), the column repair is on CS2.

The column broadcast operation is disabled when the FA_0 bit of the column repair information is set to one. The bit values for the FA_2 and FA_1 bits of that column repair information are not considered when the FA_0 bit is set to one, so the bit values for the FA_2 and FA_1 bits are shown as “don't care” or x values in the truth table 500. The bit values of the FA_2 bit and the FA_1 bit are output as the repair value when the FA_0 bit is set to one (similar to row 506). For example, when the FA_2 bit is set to zero and the FA_1 bit to one, indicating the column repair is on CS0, but the FA_0 bit is set to one, the bit values of the FA_2 and FA_1 bits are both set to zero, the no repair value, when output by a fuse logic circuit (e.g., the fuse logic circuit 126 of FIG. 1 or 226 of FIG. 2). The no repair value is then stored in a column latch associated with the memory bank (e.g., the column latch 232 of FIG. 2). Additional bits in the column repair information can be used to indicate a column broadcast operation is disabled in other embodiments. Additionally or alternatively, the bit values shown in the truth table can differ in other embodiments.

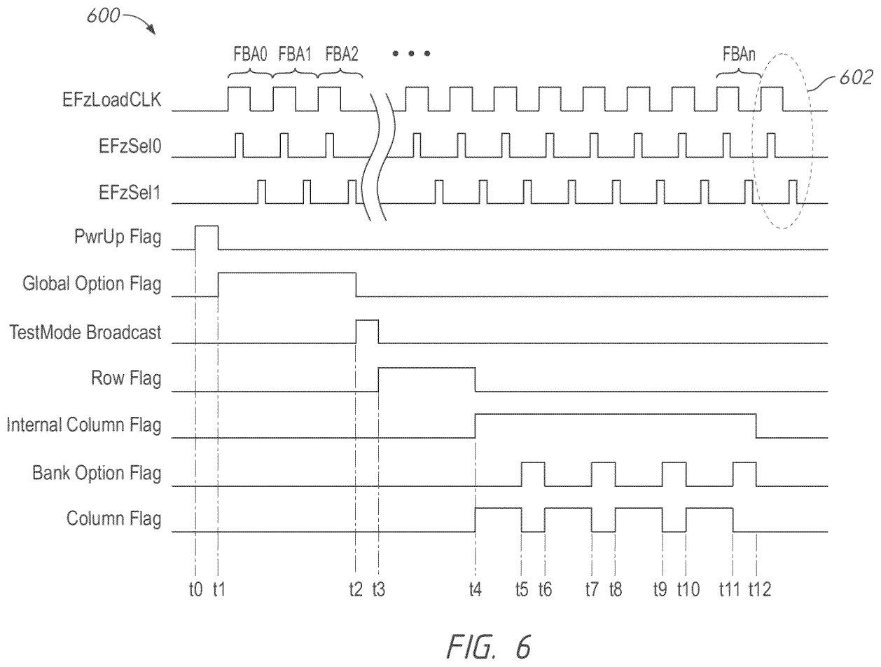

FIG. 6 illustrates an example timing diagram 600 of signals involved in broadcast operations according to an embodiment of the disclosure. The example timing diagram is described with respect to two fuse arrays (e.g., fuse array 225a and fuse array 225b of FIG. 2), although other embodiments can have one or more fuse arrays. A fuse load clock signal (EFzLoadCLK) repeatedly transitions from a high signal level (e.g., a “1”) to a low signal level (e.g., a “0”). Each transition to the high signal level can be associated with the output of a unique FBA. Thus, FBA0, FBA1, FBA2, . . . FBAn are generated in FIG. 6. In one embodiment, the fuse load clock signal (EFzLoadCLK) is generated and output by a fuse logic circuit (e.g., the fuse logic circuit 126 of FIG. 1 or 226 of FIG. 2).

Pulses occur in a first fuse select signal (EFzSel0) and in a second fuse select signal (EFzSel1) for each FBA. The pulses in the first fuse select signal and in the second fuse select signal are associated with storing information in fuse latches (e.g., row latches 219 and column latches 232 of FIG. 2). The pulses in the first fuse select signal and the second fuse select signal are offset in time from each other. In the illustrated embodiment, the pulses in the first fuse select signal occur when the fuse load clock signal is at the high signal level while the pulses in the second fuse select signal occur when the fuse load clock signal is at the low signal level.

The fuse load clock signal (EFzLoadCLK) transitions to the high signal level and back to the low signal level during the time period 602 highlighted by the dashed circle. Additionally, a pulse in the first fuse select signal (EFzSel0) occurs and a pulse in the second fuse select signal (EFzSel1) occur and are associated with the transitions in the fuse load clock signal. This time period represents a time period when a token is provided for a particular broadcast operation. The token can be global option information, row repair information, column repair information, or bank option information.

At time t0, a power up flag signal (PwrUp Flag) transitions from the low signal level to the high signal level. At time t1, the power up flag signal transitions from the high signal level to the low signal level. The power up flag signal may indicate the start of an initialization process for a memory device in one embodiment. Also, at time t1 a global option flag signal (Global Option Flag) transitions from the low signal level to the high signal level to initiate the global option broadcast. The global option flag signal remains at the high signal level during the global option broadcast. The global option flag signal transitions from the high signal level to the low signal level at the end of the global option broadcast (at time t2).

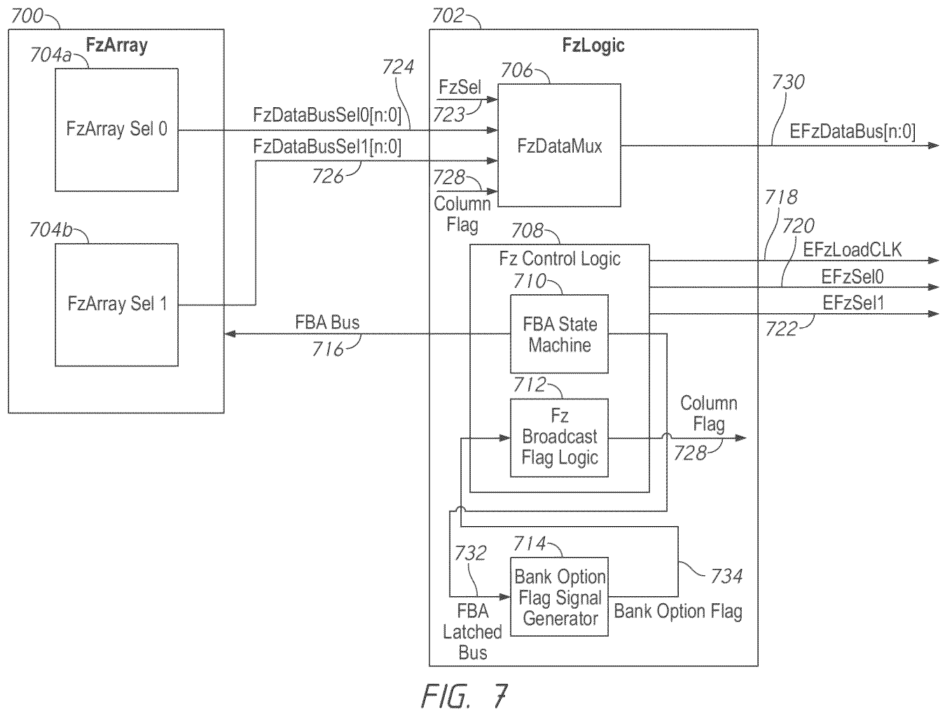

At time t2, a test mode broadcast signal (TestMode Broadcast) transitions from the low signal level to the high signal level to initiate a test mode broadcast. The test mode broadcast signal remains at the high signal level during the test mode broadcast. The test mode broadcast signal transitions from the high signal level to the low signal level at the end of the test mode broadcast (at time t3). The fuse load clock signal (EFzLoadCLK), the first fuse select signal (EFzSel0), and the second fuse select signal (EFzSel1) can be paused during the test mode broadcast and resume after the test mode broadcast is complete (after time t3). For example, in one embodiment, a fuse logic circuit may be paused to pause the output of the fuse load clock signal and the associated pulses in the first fuse select signal and the second fuse select signal. One example of a fuse logic circuit is shown and described in more detail in conjunction with FIG. 7.

At time t3, a row flag signal (Row Flag) transitions from the low signal level to the high signal level to initiate the row broadcasts. The row flag signal remains at the high signal level for the duration of all of the row broadcasts. The row flag signal transitions from the high signal level to the low signal level at the end of the row broadcasts (at time t4).

At time t4, an internal column flag signal (Internal Column Flag) and a column flag signal (Column Flag) transition from the low signal level to the high signal level to initiate the column broadcasts. The internal column flag signal remains at the high signal level for the duration of all of the column broadcasts. The internal column flag signal transitions from the high signal level to the low signal level at the end of the column and bank option broadcasts (at time t12). As will be described in more detail later, the column flag signal transitions to the low signal level when a bank option broadcast is to be performed and transitions to the high signal level when a column broadcast is to be performed.

At time t5, a bank option flag signal (Bank Option Flag) transitions from the low signal level to the high signal level to initiate a first bank option broadcast and the column flag signal transitions from the high signal level to the low signal level to pause or end the column broadcast. At time t6, the bank option flag signal transitions from the high signal level to the low signal level to end the bank option broadcast and the column flag signal transitions from the low signal level to the high signal level to resume the column broadcast or initiate a new column broadcast at a new memory bank. At time t7, the bank option flag signal transitions from the low signal level to the high signal level to initiate another bank option broadcast and the column flag signal transitions from the high signal level to the low signal level to pause or end the column broadcast. At time t8, the bank option flag signal transitions from the high signal level to the low signal level to end the bank option broadcast and the column flag signal transitions from the low signal level to the high signal level to resume the column broadcast or initiate a new column broadcast at a new memory bank. At time t9, the bank option flag signal transitions from the low signal level to the high signal level to initiate another bank option broadcast and the column flag signal transitions from the high signal level to the low signal level to pause or end the column broadcast. At time t10, the bank option flag signal transitions from the high signal level to the low signal level to end the bank option broadcast and the column flag signal transitions from the low signal level to the high signal level to resume the column broadcast or initiate the last column broadcast at a new memory bank (i.e., the last memory bank). At time t11, the bank option flag signal transitions from the low signal level to the high signal level to initiate the last bank option broadcast and the column flag signal transitions from the high signal level to the low signal level to end the column broadcast. At time t12, the bank option flag signal transitions from the high signal level to the low signal level to end the bank option broadcast, and the internal column flag signal transitions from the high signal level to the low signal level to end the column broadcast operations.

Although the internal column flag signal remains at the high signal level for the duration of the column and the bank options broadcasts, the column flag signal controls the start and the end of the column broadcasts. The bank option broadcasts are interspersed with the column broadcasts. The bank option broadcasts can occur prior to a column broadcast that is associated with a particular memory bank, during the column broadcast for the particular memory bank, or at the end of the column broadcast for the particular memory bank.

FIG. 7 illustrates a block diagram of an example fuse array 700 and a fuse logic circuit 702 according to an embodiment of the disclosure. The fuse array 700 is depicted as including a pair of fuse arrays 704a, 704b, although other embodiments can include any number of fuse arrays. In some embodiments, the fuse array 700, the fuse logic circuit 702, and the pair of fuse arrays 704a, 704b may be an implementation of the fuse array 125 and the fuse logic 226 of FIG. 1 or the pair of fuse arrays 225a, 225b of FIG. 2, respectively.

The fuse logic circuit 702 includes a fuse data select circuit (FzDataMux) 706, a fuse control logic circuit (FzControlLogic) 708, and a bank option flag signal generator circuit 714. The fuse control logic circuit 708 includes a state machine 710 and a fuse broadcast flag logic circuit (Fz Broadcast Flag Logic) 712. The state machine 710 is configured to generate FBAs and transmit the FBAs to the fuse array 700 on an FBA bus 716. In one embodiment, during a broadcast operation, the state machine 710 increments the FBAs as the state machine 710 sequences through states until the state machine 710 reaches the last FBA. Each FBA is received by the fuse array 700 to access fuses in the fuse array 700.

In the illustrated embodiment, the fuse control logic circuit 708 (e.g., the state machine 710) outputs a fuse load clock signal (EFzLoadCLK) on signal line 718, a first fuse select signal (EFzSel0) on signal line 720, and a second fuse select signal (EFzSel1) on signal line 722. The generation of the FBAs is based on the fuse load clock signal (EFzLoadCLK). The fuse load clock signal (EFzLoadCLK), the first fuse select signal (EFzSel0), and the second fuse select signal (EFzSel1) can be implementations of the fuse load clock signal (EFzLoadCLK), the EFzSel0 signal, and the EFzSel1 signal, respectively, shown in FIG. 6.

The first fuse select signal (EFzSel0) is used to activate the fuse latches that store information output onto the fuse data bus, while the second fuse select signal (EFzSel1) is used to activate the fuse latches that store information output onto the fuse data bus. In one embodiment, the second fuse select signal (EFzSel1) and the fuse load clock signal (EFzLoadCLK) are generated based on the first fuse select signal (EFzSel0). For example, the second fuse select signal (EFzSel1) is a complement of the first fuse select signal (EFzSel0). Thus, when the signal level of the first fuse select signal (EFzSel0) is at a high signal level (e.g., “1”) the second fuse select signal (EFzSel1) is at a low signal level (e.g., “0”), and vice versa. The first fuse select signal (EFzSel0) and the second fuse select signal (EFzSel1) may be combined to produce the fuse load clock signal (EFzLoadCLK).

Information stored in the first fuse array 704a is accessed and transmitted to the fuse logic circuit 702 on a first fuse data bus (FzDataBusSel0[n:0]) 724 when a respective FBA represents a set of fuses in the first fuse array 704a. The information on the first fuse data bus 724 is received by the fuse data select circuit 706 in the fuse logic circuit 702. Information stored in the second fuse array 704b is accessed and transmitted to the fuse logic circuit 702 on a second fuse data bus (FzDataBusSel1) 726 when a respective FBA represents a set of fuses in the second fuse array 704b. The information is received by the fuse data select circuit 706 in the fuse logic circuit 702.

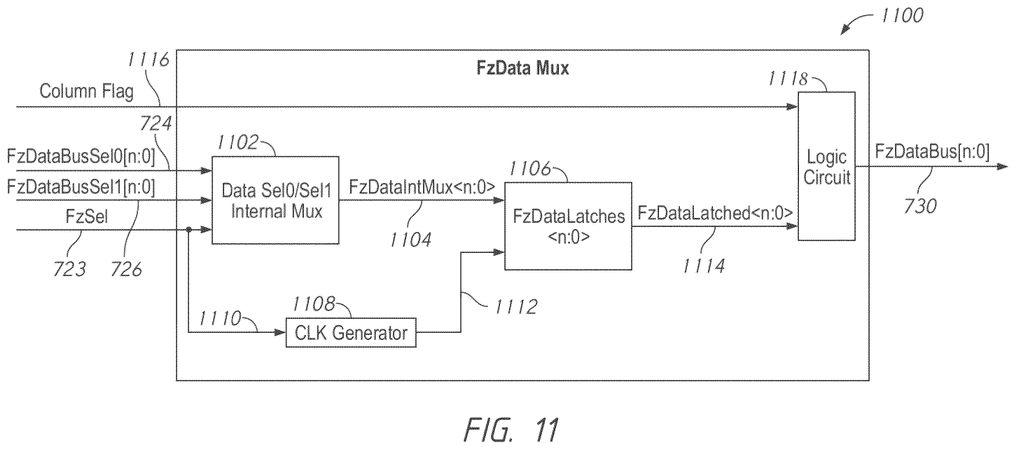

The fuse data select circuit 706 also receives the column flag signal (Column Flag) on signal line 728 and a fuse select signal (FzSel) on signal line 723. As will be described in more detail later, the fuse data select circuit 706 can output the information received on the first fuse data bus 724 and on the second fuse data bus 726 onto a fuse data bus (EFzDataBus[n:0]) 730 when the column flag signal is set to a first state (e.g., a high or (“1”) state). When the column flag signal set to a second state (e.g., a low or (“0”) state), a bank option broadcast operation is performed and the fuse data select circuit 706 outputs the bank option information received on either the first fuse data bus 724 or the second fuse data bus 726 until the state of the column flag signal transitions back to the first state. An example fuse data select circuit is described in more detail in conjunction with FIG. 11.

The fuse select signal (FzSel) can be an internal fuse select signal that toggles between high and low signal levels in one embodiment. The toggling of the fuse select signal causes toggles between the first fuse array 704a and the second fuse array 704b. The different signal levels of the fuse select signal are associated with the first fuse array 704a and the second fuse array 704b. For example, the high signal level can be associated with the first fuse array 704a. An FBA received when the fuse select signal is at the high signal level corresponds to an FBA of the first fuse array 704a. Similarly, the low signal level can be associated with the second fuse array 704b. An FBA received when the fuse select signal is at the low signal level corresponds to an FBA of the second fuse array 704b. For example, the fuse select signal can be either the first fuse select signal (EFzSel0) or the second fuse select signal (EFzSel1) in some embodiments.

The bank option flag signal generator circuit 714 receives the FBAs from the state machine 710 on an FBA latched bus 732 and outputs the bank option flag on signal line 734. The bank option flag signal generator circuit 714 is configured to determine the start of a bank option broadcast and the end of the bank option broadcast. As discussed earlier, the start of a bank option broadcast is detected based on an FBA representing a bank option start address. When the bank option start address is received by the bank option flag signal generator circuit 714 on the FBA latched bus 732, the bank option flag signal generator circuit 714 is configured to transition the state of the bank option flag signal from a first state (e.g., a low or “0”) to a second state (e.g., high or “1”).

The bank option flag signal generator circuit 714 may detect the end of the bank option broadcast in one of several ways. The end of the bank option broadcast can be detected based on an FBA that is received on the FBA latched bus 732 and represents a bank option end address. Alternatively, the end of the bank option broadcast may be determined based on a receipt of an end count value that represents the end of the bank option broadcast. When the bank option flag signal generator circuit 714 detects the end of the bank option broadcast, the bank option flag signal generator circuit 714 is configured to transition the state of the bank option flag signal to the first state (e.g., low or “0”) to indicate the end of the bank option broadcast.

The fuse broadcast flag logic circuit 712 receives the bank option flag signal on signal line 734 and outputs the column flag signal on signal line 728. The bank option flag signal and the column flag signal can be implementations of the bank option flag signal and the column flag signal, respectively, shown in FIG. 6.

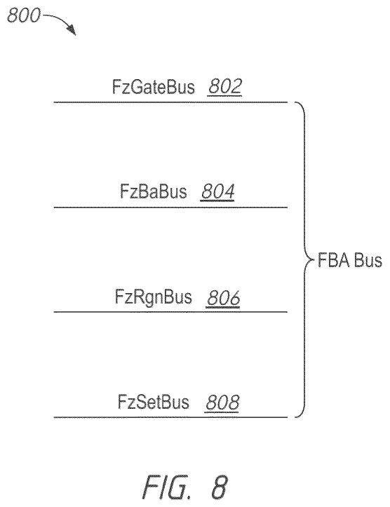

FIG. 8 illustrates example signal lines in a fuse bank address bus 800 according to an embodiment of the disclosure. The signals on the signal lines are used to access and read out data in a fuse array (e.g., the fuse array 125 of FIG. 1 or the fuse arrays 225a, 225b of FIG. 2). The signals include a fuse gate bus (FzGateBus) 802 that provides gate addresses, a fuse bank bus (FzBaBus) 804 that provides bank addresses, a fuse region bus (FzRegBus) 806 that provides region addresses, and a fuse set bus (FzSetBus) 808 that provides set signals to select different fuse read circuits in the fuse array.

In some embodiments, a fuse array can include multiple gate addresses. Each gate address may include multiple bank addresses. Each bank address can include one or more region addresses. Each region address may include multiple select signals. The gate addresses, the bank addresses, the region addresses, and the set signals will increment as a state machine sequences through states when generating FBAs (e.g., the state machine 710 of FIG. 7). For example, a gate address is provided on the fuse gate bus 802. For each gate address, the bank addresses will increment on the fuse bank bus 804 until the last bank address is reached for that gate address. For each bank address, the region addresses will increment on the fuse region bus until the last region address is reached for that bank address. For each region address, the set signals will increment on the fuse set bus 808 until the last set address is reached for that region. For example, a fuse array can have thirty-two gate addresses, thirty-two bank addresses, one to N region addresses (where N is equal to or greater than one), and two set signals. For the first gate address, the bank addresses will increment through the thirty-two bank addresses for the first gate address. For the first bank address, the region addresses will increment through the one to N region addresses for the first bank address. For the first region address, the set signals will increment through the two set signals for the first region address. When all of the set signals, the region addresses, and the bank addresses have increment through all of their states, the first gate address changes to the second gate address and the process repeats for all thirty-two gate addresses. A different number of gate addresses, bank addresses, region addresses, and select signals can be used in other embodiments.

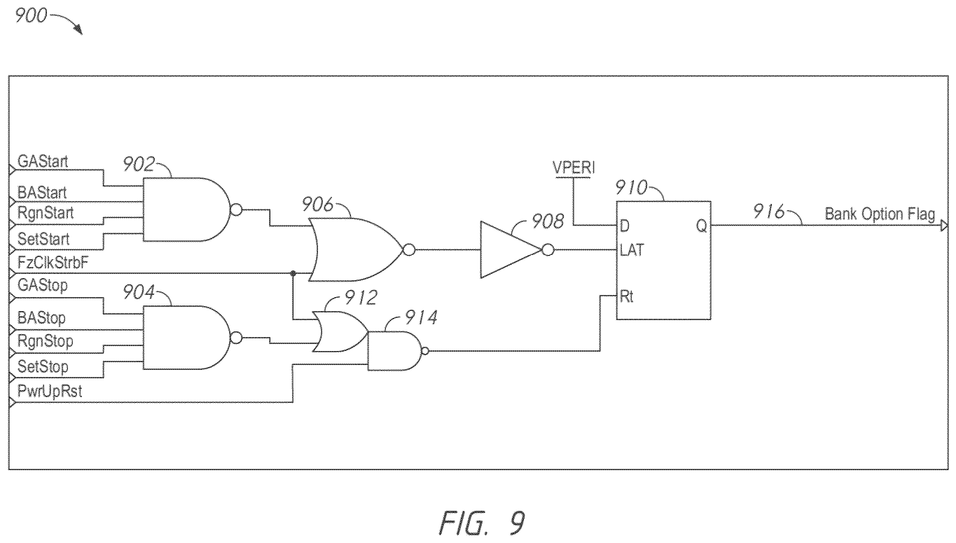

FIG. 9 illustrates a block diagram of a first example of a bank option detection circuit 900 according to an embodiment of the disclosure. The bank option detection circuit 900 can be included in the bank option flag signal generator circuit 714 shown in FIG. 7. The bank option detection circuit 900 is configured to detect a bank option start address and a bank option end address for a bank option broadcast performed for one memory bank.

The bank option detection circuit 900 includes a NAND gate 902 that receives the FBA signals shown in FIG. 8 as inputs, and another NAND gate 904 that receives the FBA signals shown in FIG. 8 as inputs. A first input of a NOR gate 906 is connected to an output of the NAND gate 902. A second input of the NOR gate 906 receives a fuse clock strobe signal (FzClkStrbF). The fuse clock strobe signal can be based on the transitions in a fuse load clock signal (EFzLoadCLK) in some embodiments. An inverter circuit 908 is connected to an output of the NOR gate 906. The output of the inverter circuit 908 is connected to an input of a latch circuit 910.

A first input of an OR gate 912 is connected to an output of the NAND gate 904. A second input of the OR gate 912 receives the fuse clock strobe signal. A first input of a NAND gate 914 is connected to an output of the OR gate 912. The second input of the NAND gate 914 receives a power up reset signal (PwrUpRst). The power up reset signal may be based on an external reset signal that is received by the memory device. An output of the NAND gate 914 is connected to the reset input of the latch circuit 910.

The NAND gate 902 detects a bank option start address and the NAND gate 904 detects a bank option end address. During a column broadcast operation to a memory bank, only one FBA is the bank option start address for the memory bank. For example, the gate address start signal, the bank address start signal, the region start signal, and the section start signal can all have the same signal level, such as a high (“1”) signal level, when an FBA is the bank option start address. Similarly, the bank address start signal, the region start signal, and the section start signal can all have the same signal level, such as a high (“1”) signal level, when an FBA is the bank option end address. As such, the output of the NAND gate 902 will be at low (“0”) signal level only once for a memory bank, and the output of the NAND gate 904 will be at a low signal level only once for a memory bank.

The fuse clock strobe signal toggles between a high signal level and a low signal level based on the pulses in a clock signal (e.g., the fuse load clock signal). When the fuse clock strobe signal is at the low signal level, the output of the NOR gate is at a high signal level, and the output of the inverter circuit 908 is at a low signal level. The latch circuit 910 receives the low signal level from the inverter circuit 908, which opens the latch circuit 910 and causes the bank option flag signal on signal line 916 to transition to the high signal level. The high signal level of the bank option flag signal indicates the start of a bank option broadcast operation.

When the output of the NAND gate 904 is at a low signal level, and the fuse clock strobe signal is at a low signal level, the output of the OR gate 912 is at a low signal level. When the power up reset signal is at the low signal level, and the output of the OR circuit 912 is a low signal level, the output of the NAND gate 914 transitions to a high signal level. The latch circuit 910 receives the high signal level from the NAND gate 914, which resets the latch circuit 910 and causes the bank option flag signal on signal line 916 to transition to the low signal level. The low signal level of the bank option flag signal indicates the end of the bank option broadcast.

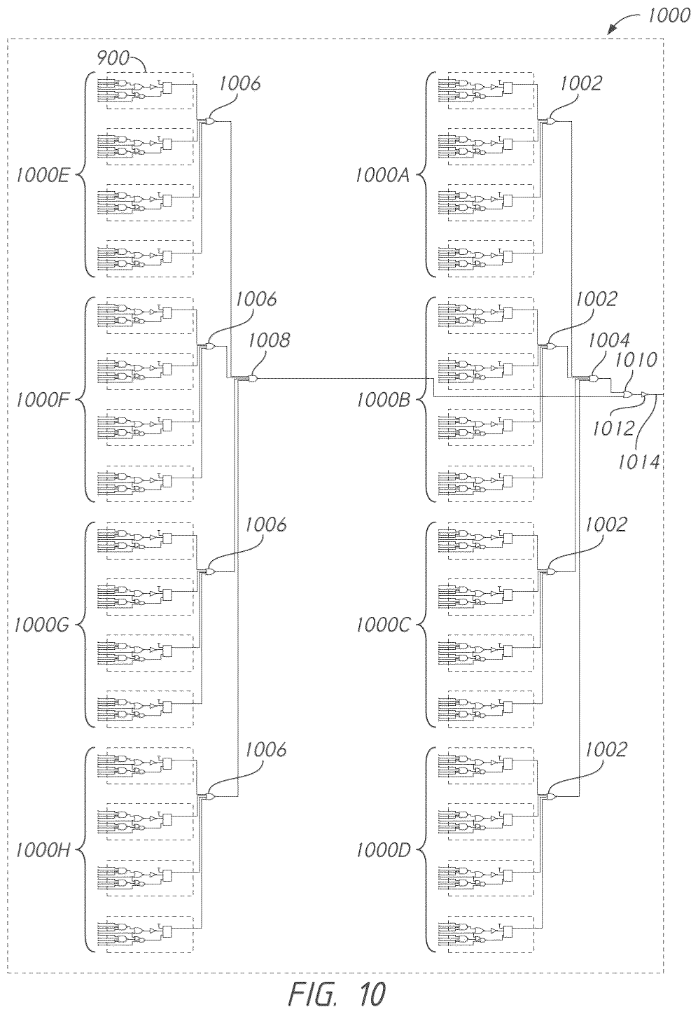

FIG. 10 illustrates a block diagram of an example arrangement 1000 of the bank option detection circuits 900 shown in FIG. 9 according to an embodiment of the disclosure. The arrangement 1000 of the bank option detection circuits 900 can be included in the bank option flag signal generator circuit 714 shown in FIG. 7. Each bank option detection circuit 900 is configured to detect bank option start addresses and bank option end addresses for the bank option broadcasts to be performed for all of the memory banks.

In one embodiment, a bank option detection circuit 900 is provided for each memory bank. For example, in one embodiment there are thirty-two memory banks. Accordingly, as shown in FIG. 10, there are thirty-two bank option detection circuits 900.

The bank option detection circuits 900 are arranged into groups. In FIG. 10, the bank option detection circuits 900 are arranged into eight groups 1000A, 1000B, 1000C, 1000D, 1000F, 1000G, 1000H. With four bank option detection circuits 900 in each group 1000A, 1000B, 1000C, 1000D, 1000F, 1000G, 1000H, the total number of bank option detection circuits 900 is thirty-two.

The outputs of the bank option detection circuits 900 in each group 1000A, 1000B, 1000C, 1000D are input into a NOR gate 1002. The outputs of each NOR gate 1002 are input into a NAND gate 1004. The outputs of the bank option detection circuits 900 in each group 1000E, 1000F, 1000G, 1000H are input into a NOR gate 1006. The outputs of each NOR gate 1006 are input into a NAND gate 1008. The outputs of the NAND gates 1004, 1008 are input into a NOR gate 1010. The output of the NOR gate 1010 is input into an inverter circuit 1012. A bank option flag signal is output onto the signal line 1014. In one embodiment, the signal line 1014 is implemented as the signal line 734 in FIG. 7. Essentially, the bank option detection circuits 900 are arranged in an OR tree arrangement.

Because a state machine increments the FBAs as the state machine sequences through states, only one bank option detection circuit 900 in FIG. 10 will assert a bank option flag signal at a time. For example, the state machine can increment the FBAs as described in conjunction with FIG. 8. Accordingly, during a column broadcast for a memory bank, only the bank detection circuit 900 associated with that memory bank will output a bank option flag signal on signal line 916 (FIG. 9) that is at a high signal level, indicating a start of a bank option broadcast for that memory bank. All of the other bank option flag signals output from the other bank option detection circuits 900 will be at a low signal level. Consequently, the bank option flag signal on the signal line 1014 will be at a high signal level when the bank option flag signal output by the bank option detection circuit 900 associated with the memory bank is at a high signal level. The bank option flag signal on signal line 1014 toggles between the high signal level and the low signal level as the column broadcasts are performed on all memory banks (e.g., see the bank option flag signal shown in FIG. 6).

FIG. 11 illustrates a block diagram of an example fuse data select circuit 1100 according to an embodiment of the disclosure. The fuse data select circuit 1100 may be implemented as the fuse data select circuit 706 shown in FIG. 7. A data multiplexer circuit (Data Sel0/Sel1 Internal Mux) 1102 in the fuse data select circuit 1100 is configured to receive information stored in the first fuse array on the first fuse data bus (FzDataBusSel0[n:0]) 724, information stored in the second fuse array on the second fuse data bus (FzDataBusSel1) 726, and the internal fuse select signal (FzSel) on the signal line 723. In some embodiments, the first fuse array, the second fuse array, and the internal fuse select signal (FzSel) may be an implementation of the first fuse array 704a, the second fuse array 704b, and the internal fuse select signal (FzSel) shown in FIG. 7, respectively.

The data multiplexer circuit 1102 outputs onto signal line 1104 either the information received on the first fuse data bus 724 or the second fuse data bus 726 based on the toggling of the fuse select signal (FzSel). The output signal FzDataIntMux[n:0] is received by fuse data latches circuit (FzData Latches [n:0]) 1106. The fuse data latches circuit 1106 can include one or more latch circuits that latch the information received in the output signal FzDataIntMux[n:0].

The fuse select signal (FzSel) is also received by a clock generator circuit (CLK Generator) 1108 on signal line 1110. The clock generator circuit 1108 outputs a clock signal on signal line 1112 that is received by the fuse data latches circuit 1106. The fuse data latches circuit 1106 outputs a data signal (FzDataLatched[n:0]) on signal line 1114 based on the clock signal on signal line 1112. The data signal can be either column repair information or bank option information, depending on the signal level of the column flag signal on signal line 1116.

A logic circuit 1118 receives the column flag signal on signal line 1116 and the data signal (FzDataLatched[n:0]) on signal line 1114. When the column flag signal is set to a high signal level, indicating a column broadcast operation is being performed, the data signal includes the column repair information. The logic circuit 1118 analyzes the column repair information to determine if one or more bits are set to a value that indicates the column broadcast is disabled (e.g., the FA_0 bit in FIG. 5). If the column repair information does not indicate the column broadcast is disabled, the logic circuit 1118 provides the column repair information on the fuse data bus (EFzDataBus[n:0]) 730. If the column repair information indicates the column broadcast is disabled, the logic circuit 1118 modifies the column repair information to include the repair value and outputs the modified column repair information onto the fuse data bus (EFzDataBus[n:0]) 730.

When the column flag signal is set to a low signal level, indicating a bank option broadcast operation is being performed, the data signal includes the bank option information. The logic circuit 1118 does not operate on the bank option information. Essentially, the bank option information passes through the logic circuit 1118 and is output onto the fuse data bus 730.

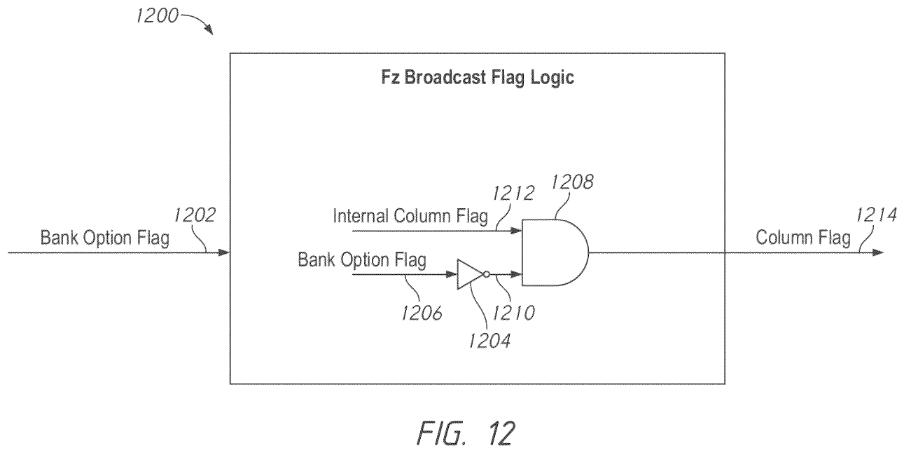

FIG. 12 illustrates an example block diagram of certain features of a fuse broadcast flag logic circuit 1200 according to an embodiment of the disclosure. The fuse broadcast flag logic circuit 1200 may be implemented as the fuse broadcast flag logic circuit 712 shown in FIG. 7. The illustrated fuse broadcast flag logic circuit 1200 depicts example logic circuitry that is used for bank option broadcasts. The bank option flag signal is input into the fuse broadcast flag logic circuit 1200 on signal line 1202 and input into an inverter circuit 1204 on signal line 1206. The output of the inverter circuit 1204 is input into a first input of an AND gate 1208 on signal line 1210. The internal column flag signal (Internal Column Flag) is input into a second input of the AND gate 1208 on signal line 1212. The column flag signal is output from the AND gate 1208 on signal line 1214.

The column flag signal on the signal line 1214 is at a low signal level (“0”) when the bank option flag signal on the signal line 1206 is at a high signal level (“1”). The column flag signal on the signal line 1214 is at the low signal level when the internal column flag signal on the signal line 1212 is at the low signal level. The column flag signal on the signal line 1214 is at the high signal level when the bank option flag signal on the signal line 1214 is at the low signal level and the internal column flag signal on the signal line 1212 is at the high signal level.

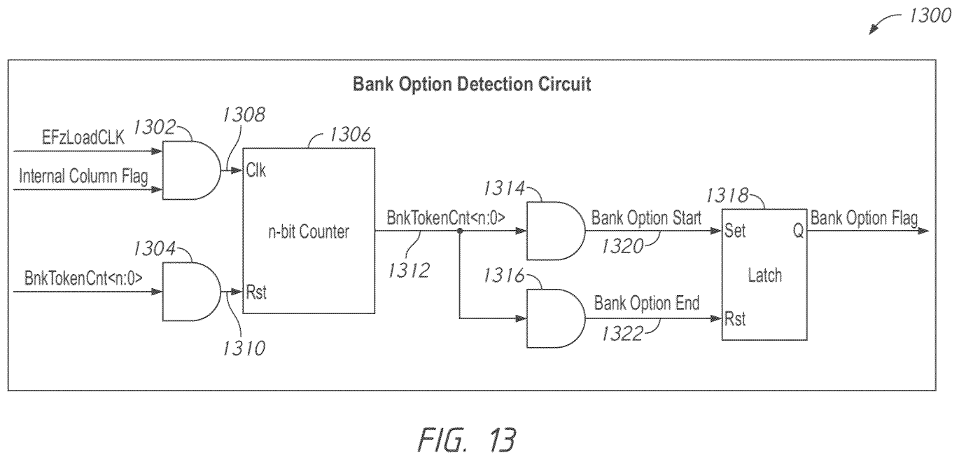

FIG. 13 illustrates a block diagram of a second example of a bank option detector circuit 1300 according to an embodiment of the disclosure. The bank option detection circuit 1300 can be included in the bank option flag signal generator circuit 714 shown in FIG. 7. The bank option detection circuit 1300 is configured to detect the start of bank option broadcasts based on the column flag signal and the end of the bank option broadcast based on end count values associated with the bank option broadcasts. Each memory bank will have same start/stop/reset count for the bank option flag signal.

The bank option detector circuit 1300 includes a decoder circuit 1302 and a decoder circuit 1304. An output of the decoder circuit 1302 is input into an n-bit counter circuit 1306 on signal line 1308. An output of the decoder circuit 1304 is input into the n-bit counter circuit 1306 on signal line 1310. The n-bit counter circuit 1306 outputs a count value (BnkTokenOut<n:0>) on signal line 1312. The count value is input into a decoder circuit 1314 and a decoder circuit 1316. An output of the decoder circuit 1314 is input into a latch circuit 1318 on signal line 1320. The output of the decoder circuit 1314 represents a bank option start signal. An output of the decoder circuit 1316 is input into the latch circuit 1318 on signal line 1322. The output of the decoder circuit 1316 represents a bank option end signal. The latch circuit 1318 outputs the bank option flag signal.

The decoder circuit 1302 receives the fuse load clock signal (EFzLoadCLK) and the internal column flag signal. The output of the detector circuit 1302 on signal line 1308 functions as a clock signal for the counter circuit 1306. The counter circuit 1306 counts the pulses in the signal on signal line 1308 and outputs the count value on signal line 1312. The decoder circuit 1314 decodes the count value (BnkTokenOut<n:0>). The signal level of the bank option start signal on signal line 1320 changes state when the count value is the start count for a bank option broadcast. The latch circuit 1318 transitions the bank option flag signal to a high signal level to indicate the start of a bank option broadcast.

The decoder circuit 1316 decodes the count value (BnkTokenOut<n:0>). The signal level of the bank option end signal on signal line 1322 changes state when the count value is the end count for the bank option broadcast. The bank option end signal resets the latch circuit 1318, which causes the bank option flag signal to transition to a low signal level to indicate the end of the bank option broadcast.

The decoder circuit 1304 also receives the count value (BnkTokenOut<n:0>). The output of the detector circuit 1304 on signal line 1310 functions as a reset signal for the counter circuit 1306. When the count value equals the reset count value, the signal on signal line 1310 resets the counter circuit 1306.

The above discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a fuse array configured to store information, the information comprising bank option information associated with a memory bank in a plurality of memory banks; and
a logic circuit configured to:
detect a start of a bank option broadcast operation;
receive the bank option information from the fuse array;
provide the bank option information to fuse latch circuits associated with the memory bank; and
detect an end of the bank option broadcast operation.

2. The apparatus of claim 1, wherein the logic circuit is configured to detect the start of the bank option broadcast operation based on a first fuse bank address, the first fuse bank address representing a bank option start address.

3. The apparatus of claim 2, wherein the logic circuit is configured to detect the end of the bank option broadcast operation based on a second fuse bank address, the second fuse bank address representing a bank option end address.

4. The apparatus of claim 3, wherein the logic circuit is configured to generate and output fuse bank addresses, including the first fuse bank address and the second fuse bank address.

5. The apparatus of claim 1, wherein the logic circuit is configured to detect the start of the bank option broadcast operation based on column flag signal.

6. The apparatus of claim 5, wherein the logic circuit is configured to detect the end of the bank option broadcast operation based on an end count value.

7. The apparatus of claim 1, wherein the bank option broadcast operation occurs after a column broadcast for the one memory bank.

8. The apparatus of claim 1, wherein the logic circuit is configured to:
set a signal level of a bank option flag signal to a first signal level based on detection of the start of the bank option broadcast operation; and
set the signal level of the bank option flag signal to a second signal level based on detection of the end of the bank option broadcast operation, wherein the second signal level differs from the first signal level.

9. The apparatus of claim 8, wherein the logic circuit is configured to:
set a signal level of a column flag signal to a third signal level based on the first signal level of the bank option flag signal; and
set a signal level of the column flag signal to a fourth signal level based on the second signal level of the bank option flag signal, wherein the fourth signal level differs from the third signal level.

10. A memory device, comprising:
a memory array comprising a plurality of memory banks;
a fuse array configured to store information, the information comprising column repair information and bank option information, the column repair information and the bank option information associated with a memory bank in the plurality of memory banks; and
a logic circuit configured to:
detect a start of a bank option broadcast operation during a broadcast operation of the column repair information;
receive the bank option information from the fuse array;
provide the bank option information to fuse latch circuits associated with the memory bank; and
detect an end of the bank option broadcast operation.

11. The memory device of claim 10, wherein the logic circuit is configured to:
detect the start of the bank option broadcast operation based on a first fuse bank address, the first fuse bank address representing a bank option start address; and
detect the end of the bank option broadcast operation based on a second fuse bank address, the second fuse bank address representing a bank option end address.

12. The memory device of claim 11, wherein the logic circuit comprises a state machine configured to generate and output fuse bank addresses, including the bank option start address and the bank option end address.

13. The memory device of claim 11, wherein:
the logic circuit comprises bank option detection circuits;
each bank option detection circuit is associated with a respective memory bank in the plurality of memory banks;
each bank option detection circuit is configured to detect the start of the bank option broadcast operation for the respective memory bank associated with the bank option detection circuit based on the bank option start address; and
each bank option detection circuit is configured to detect the end of the bank option broadcast operation for the respective memory bank associated with the bank option detection circuit based on the bank option end address.

14. The memory device of claim 10, wherein the logic circuit is configured to:
detect the start of the bank option broadcast operation based on a signal level of a column flag signal; and
detect the end of the bank option broadcast operation based on an end count value.

15. The memory device of claim 14, wherein the logic circuit is configured to:
set a signal level of a bank option flag signal to a first signal level based on detection of the start of the bank option broadcast operation;
set the signal level of the column flag signal to a second signal level based on the first signal level of the bank option flag signal, wherein the second signal level indicates the start of the bank option broadcast operation;
set the signal level of the bank option flag signal to a third signal level based on detection of the end of the bank option broadcast operation; and
set the signal level of the column flag signal to a fourth signal level based on the second signal level of the bank option flag signal, wherein the fourth signal level indicates the end of the bank option broadcast operation.

16. A method, comprising:
performing a column broadcast operation for a memory bank in a plurality of memory banks of a memory array, the column broadcast operation providing column repair information for the memory bank; and
during the column broadcast operation, performing a bank option broadcast operation for the memory array, the bank option broadcast operation providing bank option information to trim an operational parameter of the memory bank.

17. The method of claim 16, wherein the operation parameter of the memory bank comprises a setting of a sense amplifier of the memory bank.

18. The method of claim 16, further comprising:
receiving fuse bank addresses during the column broadcast operation; and
prior to performing the bank option broadcast operation, detecting a start of the bank option broadcast operation based on a received fuse bank address, the received fuse bank address representing a bank option start address.

19. The method of claim 18, further comprising providing a no repair value in the column repair information that is associated with the fuse bank start address.

20. The method of claim 16, wherein the bank option broadcast operation is performed after the column broadcast operation is completed.
